(19) United States
(12) Patent Application Publication
(10) Pub. No.: US 2017/0354036 A1
(43) Pub. Date: Dec. 7, 2017

(54) Electronic Assembly and Method for the Production thereof

(71) Applicant: Conti Temic microelectronic GmbH, Nurnberg (DE)

(72) Inventors: Andreas Albert, Hochstadt/Aisch (DE); Mathias Strecker, Crailsheim (DE); Andreas Plach, Forchheim (DE); Matthias Wieczorek, Neunkirchen am Sand (DE)

(73) Assignee: Conti Temic microelectronic GmbH, Nurnberg (DE)

(21) Appl. No.: 15/674,137

(22) Filed: Aug. 10, 2017

Related U.S. Application Data
(63) Continuation of application No. PCT/EP2016/052094, filed on Feb. 1, 2016.

(30) Foreign Application Priority Data
Feb. 10, 2015 (DE) 10 2015 202 298.6
May 7, 2015 (DE) 10 2015 208 529.5

(51) Int. Cl. H05K 1/14; H05K 3/36; H05K 3/28; H05K 1/02; H05K 1/18

(52) U.S. Cl. CPC H05K 1/144; H05K 1/0271; H05K 1/142; H05K 1/181; H05K 3/284; H05K 3/366; H05K 3/368; H05K 1/0204; H05K 2201/0129; H05K 2201/041; H05K 2201/10287; H05K 2201/10522; H05K 2203/049; H05K 2203/107; H05K 2203/1327; H05K 2203/1316

(57) ABSTRACT

The disclosure provides an electronic assembly that includes: a carrier element, a circuit carrier having a number of electronic components, a circuit board, which is electrically conductively connected to the circuit carrier, and a covering element for covering the circuit carrier. The covering element is arranged on one flat side of the circuit board and the carrier element is arranged on an opposite flat side of the circuit board. The circuit board is welded respectively to the carrier element and to the covering element. The disclosure further relates to a method for producing such an electronic assembly.

### CROSS-REFERENCE TO RELATED APPLICATIONS

This application claims the benefit of PCT Application PCT/EP2016/052094, filed Feb. 1, 2015, which claims priority to German Application DE 10 2015 202 298.6, filed Feb. 10, 2015 and German Application DE 10 2015 208 529.5, filed May 7, 2015. The disclosures of the above applications are incorporated herein by reference.

### TECHNICAL FIELD

The disclosure relates to an electronic component and to a method for the production of an electronic component of this kind.

### BACKGROUND

Conventional electronic components, for example a control device of a motor vehicle which is intended to be arranged in an engine compartment, such as a transmission control device for example, are usually designed as hermetically sealed modules. These have, for sealing purposes, a metal housing through which contact pins are passed to the outside. The contact pins are sealed off by means of so-called glass encapsulations. This produces a connection between an exterior and an interior of the electronic component.

The contact pins can be electrically conductively connected, for example, to a flexible printed circuit or to a stamped grid and therefore passed to further functional elements.

A further design of a known electronic component, which is likewise hermetically sealed, comprises a carrier element which is designed, for example, as a metal plate and on which an electrical circuit is adhesively fixed, for example by means of a thermally conductive adhesive. The electronic component further comprises a printed circuit board element and a covering element. The printed circuit board element is arranged between the carrier element and the covering element, wherein a connection between the covering element and the printed circuit board element is implemented by means of an oil-tight adhesive bond, for example a liquid adhesive or an adhesive tape.

A further design of an electronic component is known from DE 10 2012 213 916 A1. Here, an electronic module for a vehicle has a covering element, a structural part carrier printed circuit board element, a carrier element having a first side and a second side, a printed circuit board element and at least one contact-making element which is designed to provide a conductive contact-connection between the structural part carrier printed circuit board element and the printed circuit board element, wherein the covering element and the structural part carrier printed circuit board element are arranged on the first side of the carrier element. In this case, it is provided that the printed circuit board element is arranged on the second side of the carrier element, and that the carrier element has at least one opening through which the contact-making element is passed.

### SUMMARY

One aspect of the disclosure provides an electronic component that includes a carrier element, a circuit carrier, a printed circuit board, and a covering element. The circuit carrier includes a number of electronic structural parts. The printed circuit board is electrically conductively connected to the circuit carrier. In addition, the covering element is for covering the circuit carrier and is arranged on a flat side of the printed circuit board. The carrier element is arranged on an opposite flat side of the printed circuit board. The printed circuit board is welded respectively to the carrier element and to the covering element.

Implementations of the disclosure may include one or more of the following optional features. The electronic component is suitable for arrangement in a motor vehicle, for example as a gear mechanism control device. The weld connection between the printed circuit board and the covering element produces a media-tight, for example fluid-tight, interior in which the circuit carrier including the electronic structural parts is located. The weld connections between the printed circuit board and the covering element and also the carrier element are of mechanically particularly stable design compared to adhesive connections, so that sealing of the circuit carrier is ensured over the long term.

In some implementations, the printed circuit board is provided with a weldable layer for each welded connection. For example, the weldable layer is in the form of a thermoplastic layer and is applied to the printed circuit board, for example, by lamination. As an alternative, the weldable layer may also be in the form of a metallic layer. The metallic layer can be applied to the printed circuit board, for example, by way of screen printing or a so-called ink jet method.

In some examples, the circuit carrier is thermally coupled to the carrier element. As such, the circuit carrier is adhesively connected to the carrier element, for example, by way of a thermally conductive adhesive. Waste heat from the circuit carrier can therefore be discharged directly by way of the carrier element.

In some implementations, the printed circuit board is electrically conductively connected to the circuit carrier by way of at least one electrical connecting element. For example, the at least one electrical connecting element is in the form of bonding wire.

In a method for producing the described electrical component, the printed circuit board is welded respectively to the carrier element and to the covering element.

The method allows an electronic component with amedia-tight, fluid-tight interior to be produced in a simple manner, so that the circuit carrier with the electronic structural parts is protected against external influences, such as transmission oil or metal chips for example.

In some implementations, the method provides that the printed circuit board is welded respectively to the carrier element and to the covering element by friction stir welding and/or laser welding. A mechanically particularly stable weld connection may be established in this way.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 schematically shows a sectional illustration of an electronic component according to the prior art.

FIG. 2 schematically shows a sectional illustration of a further electronic component according to the prior art.

FIG. 3 schematically shows a sectional illustration of an exemplary electronic component according to the disclosure.

Like reference symbols in the various drawings indicate like elements.

### DETAILED DESCRIPTION

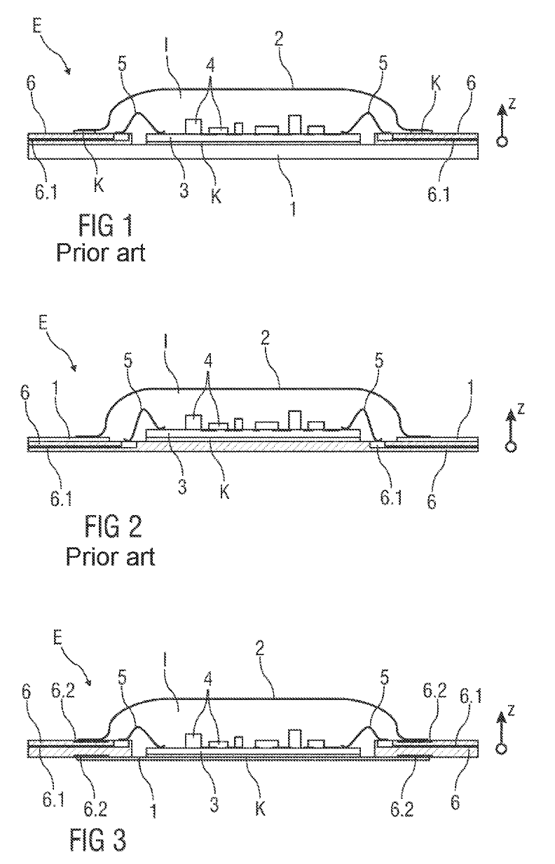

FIG. 1 shows a sectional illustration of, in particular a longitudinal section through, an electronic component E shown in DE 10 2012 213 916 A1 mentioned at the outset. The electronic component E is, for example, a control device for a motor vehicle, for example a transmission control device, and includes a carrier element 1 and a covering element 2.

A circuit carrier 3, which holds a number of electronic structural parts 4 that are combined to form an electrical circuit, is arranged in an interior I of the electronic component E between the carrier element 1 and the covering element 2. As shown, the circuit carrier 3 is electrically conductively connected to a printed circuit board 6 by means of two electrical connecting elements 5.

As shown in the electronic component E, this therefore results in a layer structure in the direction of a vertical axis z that includes the carrier element 1 with the printed circuit board 6 and the circuit carrier 3 mounted on the carrier element 1, where the circuit carrier 3 and a section of the printed circuit board 6 are closed off by the covering element 2. The constituent parts of the shown electronic component E will be explained in more detail below.

The carrier element 1 is, for example, a metallic base plate, such as an aluminum plate, which holds the circuit carrier 3 and the printed circuit board 6 on a flat side.

The circuit carrier 3 is, for example, in the form of a low-temperature cofired ceramic or micro printed circuit board and is cohesively connected to the carrier element 1 by an adhesive K, for example by means of a thermally conductive adhesive. The circuit carrier 3 is arranged entirely in the interior I of the electronic component E and includes, as electronic structural parts 4, for example, capacitors, resistors, packaged and/or unpackaged semiconductor components etc., which are adhesively bonded and/or soldered to the circuit carrier 3 for example.

The printed circuit board 6, which is further arranged on the carrier element 1, is formed from an electrically insulating substrate, for example epoxy resin, and has at least one layer of electrically conductive conductor tracks 6.1, where one conductor track 6.1 is shown by way of example. As an alternative, the printed circuit board 6 can may be of mechanically flexible design.

The printed circuit board 6 is arranged both in the interior I and in an exterior of the electronic component E and, analogously to the circuit carrier 3, cohesively connected in an oil-tight manner to the carrier element 1 by means of a further adhesive K, for example a liquid adhesive or an adhesive tape.

The printed circuit board 6 forms a connection between the exterior and the interior I. In the region of the circuit carrier 3, the printed circuit board 6 has a cutout within which the circuit carrier 3 is arranged.

The electrical connecting elements 5 which, as shown, are each designed as bonding wire, are provided in order to electrically connect the circuit carrier 3 to the printed circuit board 6.

The covering element 2, which is connected to the printed circuit board 6 in a cohesive and sealing manner by a further adhesive K, is provided in order to protect the electronic structural parts 4 on the circuit carrier 3 and also the electrical connecting elements 5 against external influences, such as transmission oil, metal chips etc., for example, and other conductive deposits.

As already described in DE 10 2012 213 916 A1, the adhesive connection between the covering element 2 and the printed circuit board 6 is subjected to mechanical stress on account of different coefficients of thermal expansion of the printed circuit board 6, of the covering element 2 and of the adhesives K. For example, the adhesive bond is subjected to shear stress, and this may lead to failure of the adhesive connection. As a result, it is possible that leaks may be produced, and therefore, in particular, the hermetic sealing of the interior I can no longer be ensured.

A further electronic component E, which is likewise known from DE 10 2012 213 916 A1, is illustrated in FIG. 2. In this example, FIG. 2 shows a sectional illustration of, in particular a longitudinal section through, a further electronic component E. Here, the layer structure is changed in relation to the electronic component E shown in FIG. 1 to the effect that the covering element 2 is connected to the carrier element 1. The carrier element 1 is therefore situated on the printed circuit board 6 which, for its part, is of continuous design without a cutout and holds the circuit carrier 3. In other words: the order of the carrier element 1 and the printed circuit board 6 is interchanged with respect to the covering element 2 in the example shown in FIG. 2.

Since the printed circuit board 6 is further intended to provide the function of connecting the electronic structural parts 4, which are arranged in the interior I, into the exterior, a link from the circuit carrier 3 in the interior Ito the printed circuit board 6 is required. As such, an opening is made in the carrier element 1. The opening allows the electronic structural parts 4 to be electrically connected to the printed circuit board 6. In this case, the electrical connecting elements 5 are passed through the opening to the printed circuit board 6.

The printed circuit board 6 is adhesively bonded in an oil-tight manner and over a large surface area to the carrier element 1 by means of an adhesive K, for example a liquid adhesive or adhesive tape. As an alternative, the covering element 2 and the carrier element 1 can also be welded to one another or connected to one another by means of an adhesive compound or an encapsulation compound.

Since the order here between the carrier element 1 and the printed circuit board 6 is interchanged, the cohesive linking of the covering element 2 is mechanically more stable than in the prior art example according to FIG. 1.

For further improved sealing of the interior I and also improved temperature control of the electronic component E in comparison to the known electronic components E described in FIG. 1 and FIG. 2, the disclosure proposes an electronic component E as is shown and described in more detail in FIG. 3.

FIG. 3 shows a sectional illustration ofa longitudinal section through, an example according to the disclosure of an electronic component E.

The electronic component E includes, analogously to the prior art, a carrier element 1, a covering element 2, a circuit carrier 3 with a number of electronic structural parts 4, and a printed circuit board 6 which is electrically conductively connected to the circuit carrier 3 by means of electrical connecting elements 5.

The design of the electronic component E is analogous to the design shown in FIG. 1, wherei the printed circuit board 6 and the circuit carrier 3 are arranged on the carrier element 1, and where the circuit carrier 3 and a section of the printed circuit board 6 are closed off by the covering element 2.

The carrier element 1 has a lower material thickness (running in the direction of the vertical axis z) in comparison to the prior art example shown in FIG. 1.

The essential difference here is that the covering element 2 is not adhesively bonded to the printed circuit board 6, but rather is welded. Furthermore, the printed circuit board 6 is welded to the carrier element 1. As such, the printed circuit board 6 has a greater material thickness (running in the direction of the vertical axis z) in comparison to the prior art example shown in FIG. 1. The printed circuit board 6 has a weldable layer 6.2 in the respective regions of the weld connection. Suitable welding methods include friction stir welding and laser welding.

The weldable layers 6.2 are, for example, in the form of metallic layers and may be applied to the printed circuit board 6 by screen printing. As such, a solderable paste is applied to a printed circuit board surface. The solderable paste may include, for example, silver, a silver alloy, copper or a copper alloy. As an alternative, the weldable layers 6.2 may also each be in the form of a thermoplastic layer and be applied to the printed circuit board 6, for example, by lamination or already be incorporated in the printed circuit board 6.

In the electronic component E according to the disclosure, the covering element 2 and the carrier element 1 are connected to the printed circuit board 6 in a fluid-tight and temperature-resistant manner. In addition, the weld connection is also highly stable to mechanical stress. As a result, the interior I is protected against external influences in an optimum manner.

Furthermore, the circuit carrier 3 is adhesively connected to the carrier element 1, so that waste heat may be dissipated directly by the carrier element 1. A thermally conductive adhesive may be used as adhesive K for the purpose of adhesive connection.

A number of implementations have been described. Nevertheless, it will be understood that various modifications may be made without departing from the spirit and scope of the disclosure. Accordingly, other implementations are within the scope of the following claims.

What is claimed is:

1. An electronic component comprising:
a carrier element;
a circuit carrier having a number of electronic structural parts;
a printed circuit board electrically conductively connected to the circuit carrier, the printed circuit board having a flat side and an opposite flat side, the carrier element arranged on the opposite flat side of the printed circuit board; and
a covering element for covering the circuit carrier, the covering element is arranged on the flat side of the printed circuit board,
wherein the printed circuit board is respectively welded to the carrier element and to the covering element.

2. The electronic component of claim 1, wherein the printed circuit board includes a weldable layer for a respective welded connection.

3. The electronic component of claim 2, wherein the weldable layer is in a form of a thermoplastic layer.

4. The electronic component of claim 2, wherein the weldable layer is in a form of a metallic layer.

5. The electronic component of claim 1, characterized in that the circuit carrier is thermally coupled to the carrier element.

6. The electronic component of claim 5, characterized in that the circuit carrier is adhesively connected to the carrier element by means of a thermally conductive adhesive.

7. The electronic component of claim 1, wherein the printed circuit board is electrically conductively connected to the circuit carrier by at least one electrical connecting element.

8. The electronic component of claim 7, wherein the at least one electrical connecting element is in a form of bonding wire.

9. A method for producing an electronic component, the method comprising:
providing a printed circuit board having a flat side and an opposite flat side;
electrically conductively connecting a circuit carrier to the printed circuit board, the circuit carrier having a number of electronic structural parts;
arranging a carrier element on the opposite flat side of the printed circuit board;
arranging a covering element on the flat side of the printed circuit board, the covering element configured to cover the circuit carrier; and
welding the printed circuit board to the carrier element and to the covering element.

10. The method of claim 9, wherein the printed circuit board is welded respectively to the carrier element and to the covering element by friction stir welding and/or laser welding.
